(19) United States
(12) Patent Application Publication
(10) Pub. No.: US 2013/0017401 A1
(43) Pub. Date: Jan. 17, 2013

(54) METAL COMPONENT, METHOD FOR PRODUCING A METAL COMPONENT, AND FITTING, FURNITURE, AND/OR LARGE HOUSEHOLD APPLIANCE

(71) Applicants: Daniel Rehage, Bielefeld (DE); Lars Schrubke, Kirchlengern (DE); Klaus-Dieter Kampmeier, Fischbach (DE)

(72) Inventors: Daniel Rehage, Bielefeld (DE); Lars Schrubke, Kirchlengern (DE); Klaus-Dieter Kampmeier, Fischbach (DE)

(73) Assignees: BAF INDUSTRIE-UDE OBERFLACHENTECHINK GMBH, Fischbach (DE); PAUL HETTICH GMBH & CO. KG, Kirchlengen (DE)

(21) Appl. No.: 13/577,349

(22) PCT Filed: Feb. 3, 2011
(86) PCT No.: PCT/EP11/51578

§ 371 Date: Oct. 2, 2012

(30) Foreign Application Priority Data
Feb. 9, 2010 (DE) 10 2010 000 344.1

(51) Int. Cl. B32B 15/08; B05D 1/02; C23C 14/28; B05D 3/00

(52) U.S. Cl. 428/457; 427/299; 427/447; 427/596

(57) ABSTRACT

A metal component for one or more of a fitting, a piece of furniture, and a household appliance. The metal component, at least sectionally, has a coating which comprises at least one perfluoroalkoxy copolymer. A method for producing a metal component for one or more of a fitting, a piece of furniture, and a household appliance, wherein the method comprises the following steps: forming the metal component; pretreating the metal component; applying a coating, which coating comprises at least a perfluoroalkoxy copolymer; curing the applied coating; and cooling the coated metal component.

### CROSS-REFERENCE TO RELATED APPLICATION

This application is a national stage of International Application PCT/EP2011/051578, filed Feb. 3, 2011, and claims benefit of and priority to German Patent Application No. 10 2010 000 344.1, filed Feb. 9, 2010, the content of which Application is incorporated by reference herein.

### BACKGROUND AND SUMMARY

The present disclosure relates to a metal component, in particular for a fitting, a piece of furniture, and/or a large household appliance. The present disclosure further relates to a method for the production of the metal component and for a fitting, a piece of furniture, and/or a large household appliance including the metal component.

Metal components, in particular fittings in household appliances, are subjected to extreme conditions. For example, grease and dirt accumulations, which substantially influence the service life and operation of such components.

Fittings are known, which are provided with a polytetrafluoroethylene, or PTFE, coating for improving their cleaning capability. However, PTFE is difficult to process and requires a high work and energy consumption during the coating method. In addition, PTFE coatings have the tendency to chip off at higher surface tensions and in the event of mechanical strain.

Embodiments of the present disclosure provide for a metal component which can be produced cost-effectively and additionally can be cleaned easily. Embodiments of the present disclosure also provide for a method for the production of the metal component.

Embodiments of the present disclosure are also found in the claims.

A metal component, in particular for a fitting, a piece of furniture, and/or a household appliance, at least sectionally, has a coating according to embodiments of the present disclosure. The coating may comprise at least one perfluoroalkoxy copolymer, orPFA, formed from tetrafluoroethylene, or PTFE, and a perfluoro, or alkyl vinyl ether.

The copolymer can, for example, be implemented as a random copolymer, gradient copolymer, block or graft copolymer, but may be as an alternating copolymer.

The coating has outstanding friction properties, a high alternating temperature resistance, and in addition, in relation to PTFE, improved anti-adhesion properties, lesser tendency to chip off, and an improved scratch resistance.

In an advantageous embodiment according to the present disclosure, the coating contains at least 80% of a polymer blend made of the copolymer and a polyether ketone. Polyether ketones are high-temperature resistant, so that the usage temperature of the coated fitting is increased from approximately 300° C. to approximately 350° C. Polyether ketones additionally have an outstanding impact resistance and increase the hardness of the coating.

This is the case, for example, if polyether ether ketone, or PEEK, is advantageously used as the polyether ketone.

Surprisingly, it has been established that already a mass proportion of 10-40% of a polyether ketone results in a multiplication of the scratch resistance of the PFA coating and a stronger adhesion of the coating on the metal surface of the component.

It is advantageous, according to an embodiment of the present disclosure, if the fitting has a dynamic coefficient of friction between 0.15-0.4 through a corresponding treatment of the coating. The coating can, therefore, advantageously be applied to running surfaces of pullout guides, for example, whereby the running quality of the pullout guides is improved and simultaneously the use of such pullout guides in ovens is made possible because of the high-temperature-resistant PFA coating.

Furthermore, it is advantageous, according to an embodiment of the present disclosure, if the surface of the coating has a ball indentation hardness according to DIN 53456 between 30-95 N/mm². Fittings, furniture, and/or household appliances are sometimes subjected to high mechanical strains. Through an appropriate formulation of a polymer blend or another treatment of the PFA-copolymer of the coating, the ball indentation hardness can be optimized in such a manner that the metal component has a high resistance to mechanical strains and abrasive forces.

It is advantageous, according to an embodiment of the present disclosure, if the coating is arranged in multiple layers. This is the case, for example, if various regions of the metal component, for example, of the fitting, are subjected to different forces and conditions. Thus, the outer surfaces of a pullout guide in an oven are subjected to a high degree of soiling from fat sprays and food residues, for example, so that a high cleaning capability but also a corrosion safeguard must be produced for the surfaces. The running surfaces of the pullout guide are subjected to rather high mechanical strains. The coating, according to an embodiment of the present disclosure, can be optimized, depending on the surface, through a multilayered structure in such a manner that the advantageous properties of the copolymer are supplemented with further layers of polymer blends, which primarily contain PFA, however.

For example, it is advantageous, according to an embodiment of the present disclosure, in the case of pullout guides, if the coating has at least two layers, the uppermost layer advantageously having a dynamic coefficient of friction of less than 0.3 and therefore a high sliding capability. The layer arranged underneath has a ball indentation hardness of at least 0.35 N/mm², for example, at least 0.8 N/mm², so that it represents an increased scratch and corrosion protection because of its hardness.

For an effective corrosion protection, it is advantageous, according to an embodiment of the present disclosure, if the uppermost layer has at most 20% of the layer thickness of the underlying layer.

For example, it is advantageous, according to an embodiment of the present disclosure, to improve the running quality of pullout guides if lubricant is incorporated in the coating, for example, in the region of the running surfaces of pullout guides, so that the lubricant is fixed by the coating on the surface of the fitting.

For an improved appearance, it is advantageous, according to an embodiment of the present disclosure, if the coating is transparent or translucent.

Alternatively or additionally, the coating can at least regionally have color pigments, for example, in the form of graphite, mica, titanium dioxide, or the like, which color the coating in the colors white, light gray, or anthracite, for example. Dark colors may, for example, be preferable for use in ovens, cooking devices, and fixtures for these devices. For refrigerators, the coating can also be colored white, for example, through the use of titanium dioxide. Transparent layers are used in fittings, furniture, and household appliances. Coatings for furniture are colored according to the customer desire and the chemical technical possibilities.

To prevent annealing colors, improve the corrosion protection, and achieve a specific surface structure, it is advantageous, according to an embodiment of the present disclosure, if the metal component has a metal finishing coat, to which the coating is applied.

According to the present disclosure, a method for producing a metal component comprises the following steps:

forming and/or reshaping the metal component;
pretreating the component;
applying the coating, the at least one copolymer, formed from tetrafluoroethylene and a perfluoro, or alkyl vinyl ether;
optionally curing and sintering the applied coating; and cooling the coated component.

This method can, in accordance with the present disclosure, be integrated accordingly in the mass production of fittings, furniture, and household appliances.

It is advantageous, according to an embodiment of the present disclosure, if degreasing and/or cleaning and/or washing and/or pickling of the surface of the component is performed by pretreating the metal component, so that improved adhesion of the coating on the surface is ensured. This can be performed, for example, by wet-chemical cleaning methods, but can also be achieved by thermal treatment of the components, for example.

It is advantageous, according to an embodiment of the present disclosure, if, after forming and/or reshaping the metal component and/or after pretreating the component, smoothing of the surface is performed, so that even at low layer thicknesses, the corresponding surface is completely provided with the coating and no irregularities protrude on the surface and a uniform surface is formed for the adhesion of the coating. The smoothing of the surface can be performed by grinding, polishing, blasting, or other typical methods.

To prevent annealing colors, it is, according to an embodiment of the present disclosure, advantageous if the curing and sintering of the coated component are performed under low-oxygen atmosphere.

To improve the cleaning capability, it is, according to an embodiment of the present disclosure, advantageous if laser processing of the coated surfaces is performed after the component is coated. The hydrophobia of the coating is increased and an enlargement of the contact angle of a liquid droplet on the coating surface of up to 10° is achieved. Surprisingly, it has been shown that the laser processing can be performed particularly effectively at a wavelength between 160 and 210 nm.

Furthermore, it is advantageous, according to an embodiment of the present disclosure, if the application of the coating is performed by plastic flame spraying, since a higher coating density, stronger binding forces to the metal surface and between the polymer molecules, and a high coating efficiency can thus be achieved.

According to an embodiment of the present disclosure, at least one metal component is arranged on or in a fitting, a piece of furniture, a large household appliance, for example, a refrigerator, washing machine, or oven. Extreme conditions sometimes prevail, for example, in the field of large household appliances. A coating which is used in an oven must thus have a temperature resistance of 250° C. to 300° C. and must be able to be cleaned easily of fat sprays and the like. Coatings in refrigerators and freezers cannot become brittle or fragile at low temperatures and additionally must be resistant to condensed water and ice. Coatings in dishwashers must be resistant to suds and moisture at temperatures of up to 100° C. All of these conditions are met by embodiments of the metal component according to the present disclosure, for example, a fitting, so that it is universally usable on all regions of the large household appliances. Therefore, fittings do not have to be produced specially for specific fields of application, which provides a substantial advantage with respect to work expenditure, appliance expenditure, and material expenditure.

Furniture, in the meaning of embodiments of the present disclosure, are furniture components such as drawers, but also household appliances such as ovens, dishwashers, refrigerators and freezers, washing machines, and dryers.

Other aspects of the present disclosure will become apparent from the following descriptions when considered in conjunction with the accompanying drawings.

### BRIEF DESCRIPTION OF THE DRAWINGS

FIGS. 1 to 3 show multiple views of a first embodiment of a metal component, according to the present disclosure, and shown as a pullout guide.

FIGS. 4 and 5 show two views of second embodiment of a metal component, according to the present disclosure, and shown as a pullout guide having a spray protection cap.

FIGS. 6 and 7 show two views of a third embodiment of a metal component, according to the present disclosure, and shown as an oven hinge.

FIGS. 8 and 9 show two views of a fourth embodiment of a metal component, according to the present disclosure, and shown as a refrigerator hinge.

### DETAILED DESCRIPTION

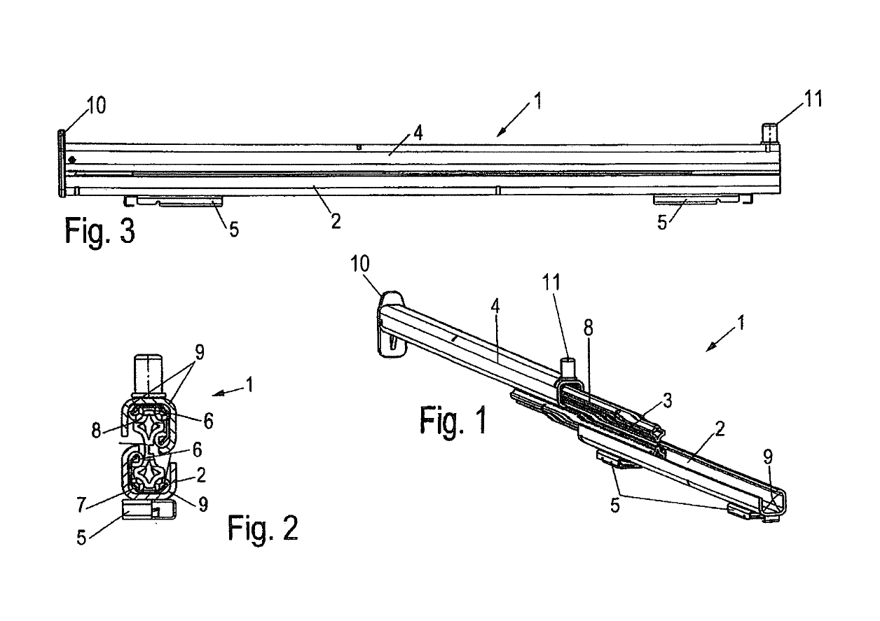

FIGS. 1-3 show a telescopic pullout guide 1. The pullout guide 1 comprises a guide rail 2, which can be fixed on a side grating in an oven, a side wall of an oven, or a furniture body. A middle rail 3 is mounted so it is movable via roller bodies 6 on the guide rail 2. The middle rail 3 is used for mounting a slide rail 4. Three runways 8 for roller bodies 6 are, respectively, implemented on the guide rail 2 and the slide rail 4 to mount the rails 2, 3, and 4. The roller bodies 6 are held as a unit on a roller body cage 7. Furthermore, a total of six runways 8 for roller bodies 6 are implemented on the middle rail 3, respectively, three runways 8 being assigned to the guide rail 2 and three runways 8 being assigned to the slide rail 4. Furthermore, telescopic pullout guides 1 can, in accordance with the present disclosure, also be implemented as a partial pullout without a middle rail 3 or as a complete or upper pullout having one or more middle rails 3.

Two clamps 5 are fixed on the guide rail 2 to fasten the pullout guide 1, for example, on a side grating of an oven. Other fastening means can, in accordance with the present disclosure, also be provided on the guide rail 2.

The pullout guide 1 is manufactured from metal, for example, stainless steel. The pullout guide 1 is provided with a perfluoroalkoxy copolymer, or PFA, coating at least on the externally accessible regions, that is, on the outer side of the guide rail 2 and the slide rail 4.

The coating primarily contains a copolymer, formed from tetrafluoroethylene and a perfluoro, or alkyl vinyl ether, for example, poly-(perfluorovinyl methyl ether).

This copolymer is known, among other things, as perfluoroalkoxylalkane and has advantageous properties in relation to PTFE with respect to its processing and also with respect to the adhesion of the polymer chains to one another.

The copolymer is accessible, or amendable, to spraying methods, for example, flame spraying, and can therefore be applied to a metal surface both in a solvent-based dispersion and also as a solvent-free polymer.

A plug 10, which is fixed on the slide rail 4, is also coated on its externally accessible regions with the PFA-containing coating. A retaining bolt 11 is also equipped with a PFA-containing coating. The inner side of the slide rail 4 and the guide rail 2, on which the runways 9 for the roller bodies 6 are implemented, does not have a coating. The middle rail 3, which is arranged entirely in the inner region of the pullout guide 1, when the slide rail 4 is arranged in the retracted position, also has no coating at least in the region of the runways 8. The runways 8 can be formed by the material of the rails 2, 3, and 4. The runways 8 and 9 are, for example, typically produced from a bent steel plate. On the outer side, easy cleaning capability is made possible by the PFA-containing coating on the rails 2 and 4. Since the usage range of the perfluoroalkoxy copolymer extends up to 300° C., the pullout guide 1 can be used, for example, particularly well in an oven, a long service life and a high running quality of the pullout guide additionally being achieved.

In order to be used in the household field, for example, in the kitchen, the coated pullout guides 1 must comply with the FDA guidelines for contact with foods. Since the coating material has been classified as harmless to health, according to various material safety data sheets, a field of use for contact with foods, for example, in ovens and on cooked food supports, is possible.

In an embodiment according to the present disclosure, the inner sides of the slide rail 4 and the guide rail 2, on which the runways 9 for the roller bodies 6 are implemented, are provided with a lubricant-containing PFA coating. The middle rail 3, which is arranged completely in the inner region of the pullout guide 1, when the slide rail 4 is arranged in the retracted position, also has this lubricant-containing coating at least in the region of the runways 8. The coating in the region of the running surfaces can include, for example, 90% PFA, 5% adhesion promoter, and 5% molybdenum sulfide in relation to mass proportions.

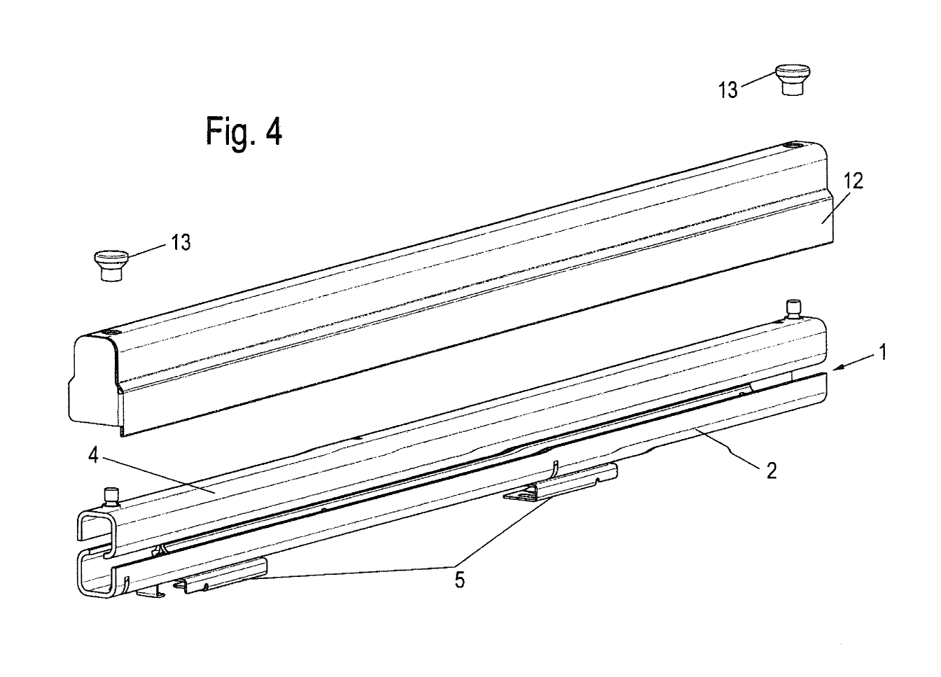

FIG. 4 shows a cover cap 12, which can be fixed on the pullout guide 1. This cover cap 12 is manufactured from a metal plate, for example, a steel plate, and is provided at least on the outside with the perfluoroalkoxy copolymer coating, which prevents fat accumulations on the metal surface, on the one hand, and also causes a moisture safeguard at temperatures of 250 to 300° C., on the other hand. The catch means 13 can also, for example, have the coating.

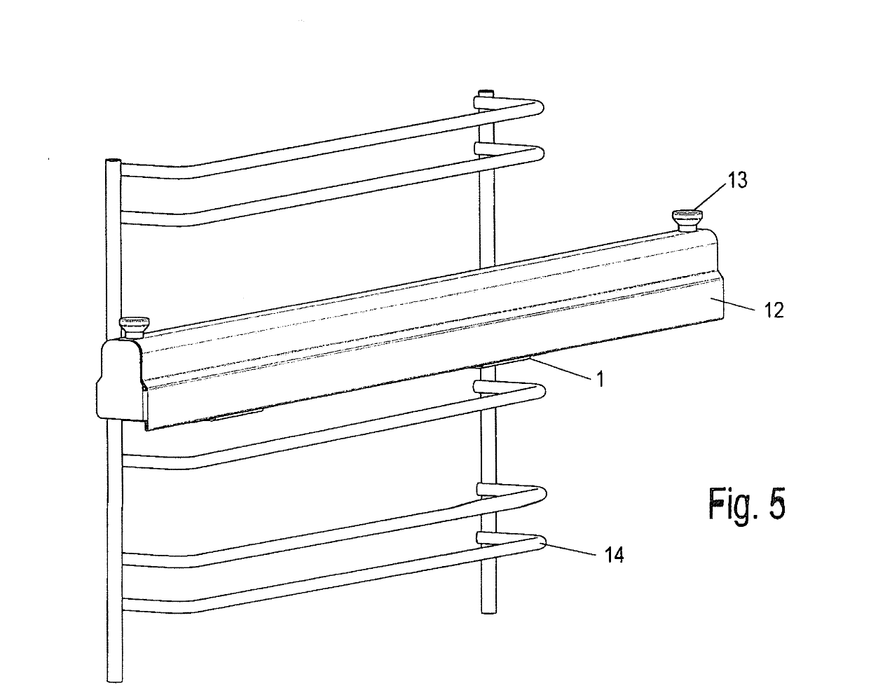

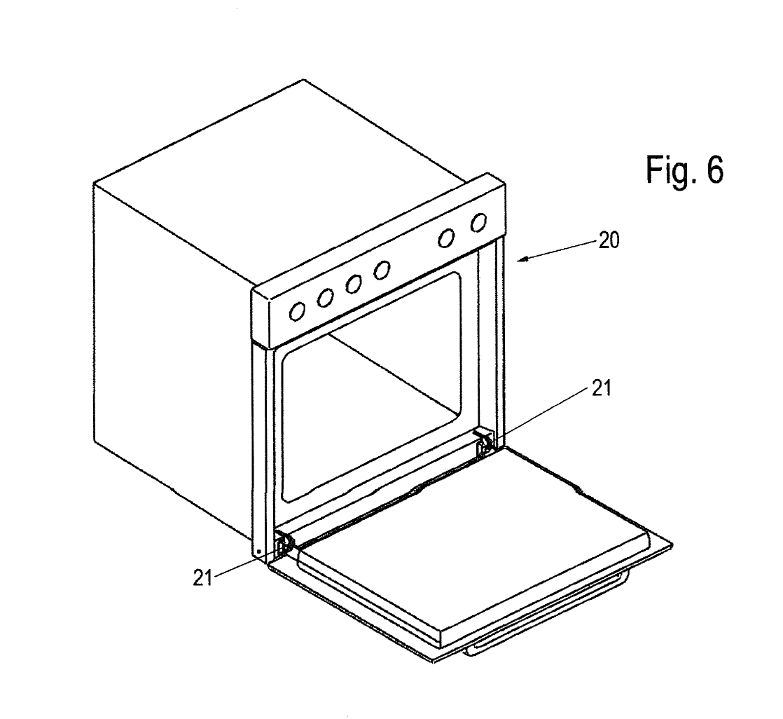

FIG. 5 shows the fixing of the pullout guide 1 with the cover cap 12 on the side grating 14 of an oven. For an advantageous cleaning capability, the side grating 14 of an oven may be provided with the coating.

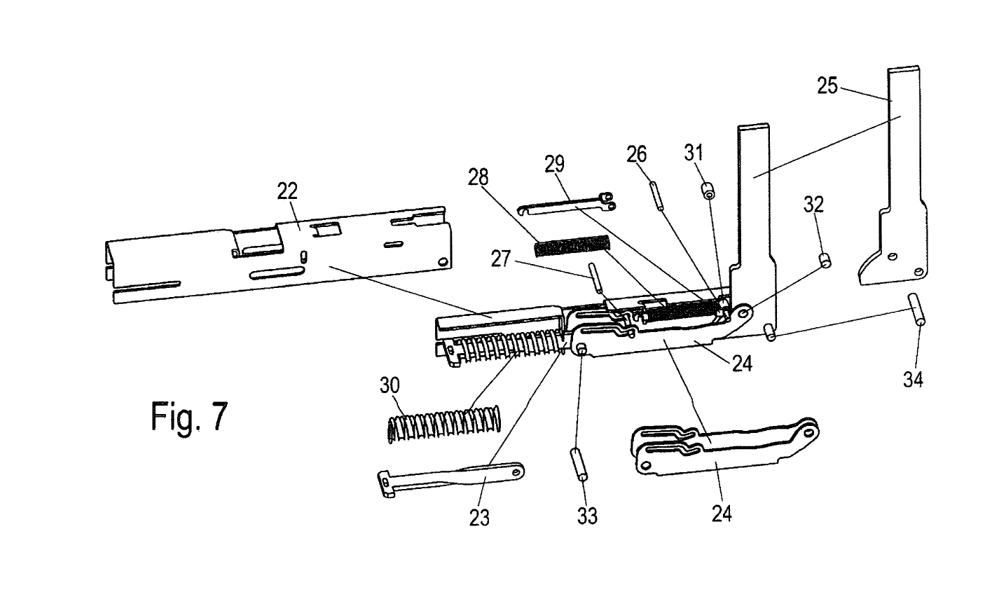

FIGS. 6-8 show an oven 20 having a hinge 21. The hinge 21 is composed of a housing 22, in which a linear lever 23 is arranged. This linear lever 23 is coupled by a rivet connection 33 to a transmission lever 24. A compensation spring 30, which is wound around the shaft of the linear lever 23 and can be tensioned by movement of the linear lever 23, extends on the longitudinal axis of the linear lever 23. The transmission lever 24 is coupled so it is pivotable to a door lever 25 via a rivet connection 32, which is coupled to an oven door. At a height of the transmission lever 24, a closing lever 29 is additionally arranged in the housing 22, which is fixed by a rivet connection 26 and which has a catch lug, which engages in a catch rivet 27, which is mounted so it is movable in a guide in the transmission lever 24. The rivet connection 26 additionally has a pressure roll 31, for partially absorbing a force which is exerted by the door lever 25 on the rivet connection 26. The shaft of the closing lever 29 is provided with a closing spring 28, which tensions and relaxes through movement of the hinge 21.

In an embodiment, according to the present disclosure, all of the above-noted components can be provided with a corresponding PFA-containing coating, for example, at least the planar regions, and, for example, the housing 21 and the door lever 25.

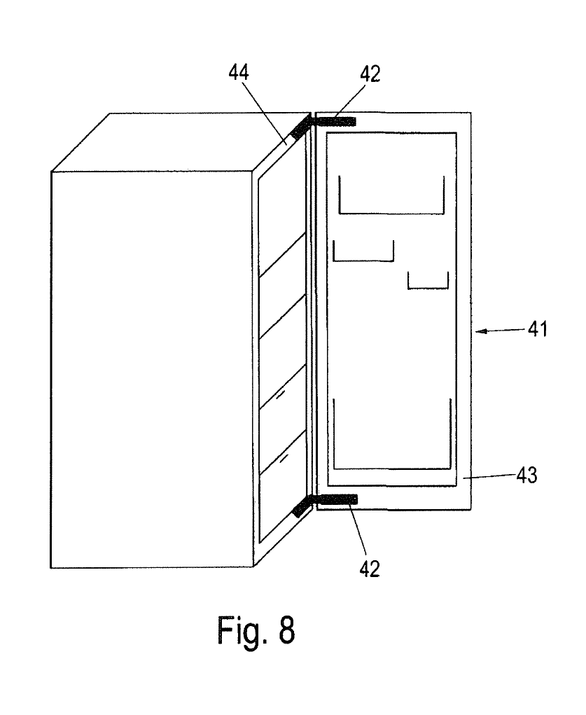

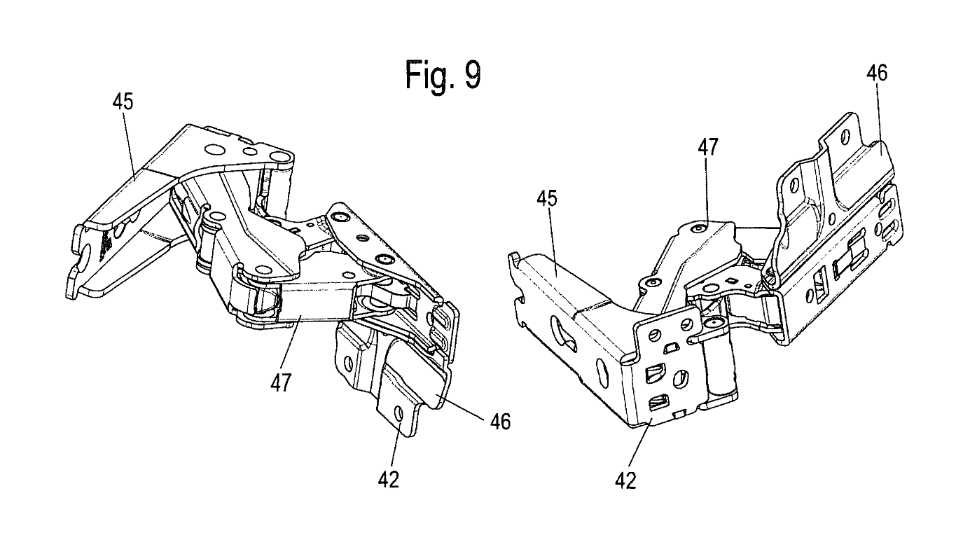

FIG. 8 shows a refrigerator 41 having hinges 42 which are fastened on the refrigerator door 43 and the refrigerator body 44 and allow the opening of the refrigerator 41. FIG. 9 illustrates an embodiment, according to the present disclosure, of such a hinge 42 having two baseplates 45, 46 and one hinge arm 47, respectively. The surface of the hinge 42 is, according to the present disclosure, completely provided with the PFA-containing coating, polymer blends having polyether ketones, for example, PEEK. The coating forms a safeguard from dirt and contaminants, which collect on the metal surface, and allows an outstanding cleaning capability of the fittings. Furthermore, the coating allows a corrosion safeguard for iron components, which are not attacked by the aggressive environmental conditions in refrigerators and freezers. PFA also adheres to the metal surfaces at temperatures of −50 to 0° C., without chipping off because of embrittlement or temperature-dependent material expansion.

The metal component, according to an embodiment of the present disclosure, for example, as a fitting, comprises all fitting devices, for example, hinges, suspensions, furniture fittings and decorative fittings for external and internal use, and pullout guides. Because of the high alternating temperature resistance, the coated fittings can be used universally both in ovens at approximately 300° C. and also in refrigerators at −50° C. Furthermore, the coated fittings can also be used in furniture under extreme climatic conditions, for example, ocean climate with salty air of high humidity.

The coating, according to the present disclosure, offers an outstanding corrosion safeguard to metal components made of steel, the coating additionally being more scratch resistant than the previously known PTFE coatings. The coating can be applied in greater layer thicknesses than PTFE. In addition, the coating is more resistant in relation to high surface tensions in comparison to a PTFE coating. This is because, among other things, the copolymer used is a thermoplastic, in which the individual polymer compounds are fused and are not merely glued together using adhesion promoters, as is the case in PTFE. The coating has a critical surface energy of 17.0 mN/m and therefore a better cleaning capability than PTFE (18 mN/m). The cleaning capability of the coating according to the present disclosure, is able to be improved advantageously.

The production of a metal component according to the present disclosure, for a fitting, a piece of furniture, and/or a household appliance, is performed according to the following method, for example.

Firstly, a metal component is brought into a predetermined form from a metal workpiece through, for example, bending, pressing, stamping, casting, and other similar processes.

Subsequently, the component is deburred and degreased and cleaned through wet-chemical pretreatment. The cleaning temperature is, for example, 50 to 100° C., or may be 60 to 80° C. After 3 to 10 min., or, for example, 4 to 6 min., of cleaning treatment, the components are first rinsed using normal water or city water at, for example, 15 to 25° C., and subsequently using demineralized water, at, for example, 15 to 25° C. The drying of the metal components is performed for approximately 5-10 min. at approximately 50 to 150° C. This can, for example, be performed with a continuously rising temperature from 80 to 150° in circulating air operation.

After the completion of the pretreatment steps, a mixture made of the copolymer, formed from tetrafluoroethylene and a perfluoro, or alkyl vinyl ether, and a primer is applied as a solvent-based dispersion to the metal surface. The primer is used as an additional adhesion promoter between the coating and the metal surface of the component. Both organic solvents and also water are considered as solvents in this case. The coating can, in accordance with the present disclosure, also be applied in multiple layers, each layer being able to have a different concentration of primers or different PFA-containing polymer blends. In addition, a cover layer, in accordance with the present disclosure, can be applied as a powder to the layers which were applied as a dispersion and dried. A one-layer system can be generated by direct application of the cover layer or a combined layer made of adhesion promoter, or primer, and cover layer, or topcoat, to the surface of the metal component. A two-layer system can include an adhesion promoter and a cover layer. A multilayer system can include at least one layer of adhesion promoter and one cover layer as well as at least one intermediate layer. Adhesion promoter, cover layer, and intermediate layer, for example, can contain, in addition to the mixture made of the copolymer, formed from tetrafluoroethylene and a perfluoro, or alkyl vinyl ether, solvents, ceramic additives as fillers or to increase the layer hardness, color pigments, PEEK, or PTFE.

A liquid adhesion promoter can also, in accordance with the present disclosure, be combined with powdered intermediate and/or cover layers.

The application of the layers is performed in a spraying method by, for example, HVLP, or high-volume low-pressure spray guns, for example, being suspended. The HVLP lacquering method is a low-pressure method in which the volatile organic compounds are reduced and therefore the environmental stress decreases. Alternatively or additionally, in accordance with the present disclosure, the coating can also be performed by electrostatic facilities, for example, by powder or wet lacquer application.

The drying of the coating is performed at 50 to 180° C., or, for example, at 80 to 150° C., over a period of time of 5 to 15 min.

The subsequent sintering process is performed at a temperature of 390 to 450° C., or, for example, 400 to 420° C., over a time of 5 to 20 min., or, for example, 8 to 15 min.

The cooling, in accordance with the present disclosure, may be performed in different temperature ramps in order to achieve the most uniform possible formation and merging of the layer during the cooling on the surface and to avoid tension cracks in the coating.

The applied dry layer thickness is 5 to 50 μm, or, for example, 15 to 35 μm after the sintering.

An alternative application method is, according to the present disclosure, PFA coating by plastic flame spraying. An advantageous application of PFA layers through plastic flame spraying is within the scope of the present disclosure. The powdered PFA copolymer or copolymer blend is melted via a suitable spraying device in an acetylene-oxygen flame beyond 3000° C. and sprayed onto the component to be coated.

Due to the high temperatures, the copolymer melts completely in the flame and is distributed more uniformly on the surface than in other application methods.

A high material density and improved binding forces of the individual polymer molecules with one another and also to the metal substrate are thus advantageously achieved. In addition, higher layer thicknesses of, for example, 100 to 700 μm can be achieved, in accordance with the present disclosure. The additional method step of sintering may, in an embodiment in accordance with the present disclosure, be omitted in this coating method.

In a post-treatment step, the hydrophobia or the anti-adhesive effect of the coating may, according to the present disclosure, be increased by laser irradiation. In this case, for example, an exciter laser, ArF, having a wavelength of 193 μm, can be used. Superficial ablation of irregularities occurs upon irradiation, whereby the anti-adhesion properties are improved and super-hydrophobic properties of the surfaces of the metal component arise, so that an improvement of the cleaning capability can, according to the present disclosure, be achieved once again.

Although the present disclosure has been described and illustrated in detail, it is to be clearly understood that this is done by way of illustration and example only and is not to be taken by way of limitation. The scope of the present disclosure is to be limited only by the terms of the appended claims.

We claim:

1. A metal component for one or more of a fitting, a piece of furniture, and a household appliance, wherein the metal component, at least sectionally, has a coating which comprises at least one perfluoroalkoxy copolymer.

2. The metal component according to claim 1, wherein the coating includes at least 80% of a polymer blend made of the copolymer and polytetrafluoroethylene.

3. The metal component according to claim 1, wherein the coating contains at least 80% of a polymer blend made of the copolymer and a polyether ketone.

4. The metal component according to claim 3, wherein the polyether ketone is polyether ether ketone.

5. The metal component according to claim 3, wherein the polymer blend contains a mass proportion of 10 to 40% of polytetrafluoroethylene or a polyether ketone and 60 to 90% of the copolymer.

6. The metal component according to claim 1, wherein a surface of the coating has a dynamic coefficient of friction between 0.15-0.4.

7. The metal component according to claim 1, wherein a surface of the coating has a ball indentation hardness according to DIN 53456 between 30-95 N/mm².

8. The metal component according to claim 1, wherein the coating is arranged in one layer or in multiple layers.

9. The metal component according to claim 1, wherein the coating has at least two layers, a first layer being arranged on a surface of the metal component and having a ball indentation hardness of at least 0.35 N/mm² and a second layer being arranged over the first layer and having a dynamic coefficient of friction of less than 0.3.

10. The metal component according to claim 9, wherein the second layer has at most 20% of the layer thickness of the underlying first layer.

11. The metal component according to one claim 1, wherein the coating contains lubricant.

12. The metal component according to claim 1, wherein the coating is transparent or translucent.

13. The metal component according to claim 1, wherein the coating contains color pigments.

14. The metal component according to claim 1, wherein the metal component has a metal topcoat.

15. A method for producing a metal component for one or more of a fitting, a piece of furniture, and a household appliance, wherein the method comprises the following steps:
forming the metal component;
pretreating the metal component;
applying a coating, which coating comprises at least a perfluoroalkoxy copolymer;
curing the applied coating; and
cooling the coated metal component.

16. The method according to claim 15, wherein the pretreating includes one or more of degreasing, cleaning, washing, and pickling of a surface of the metal component.

17. The method according to claim 15, wherein after one or both of the forming and pretreating steps, smoothing of the surface is performed.

18. The method according to claim 24, wherein the curing and sintering of the metal component are performed under low-oxygen atmosphere.

19. The method according to claim 15, wherein after the cooling of the coated metal component, laser processing of the coated surface is performed.

20. The method according to claim 15, wherein the application of the coating is performed by plastic flame spraying.

21. A household appliance includes at least one metal component according to claim 15, and the at least one metal component is arranged in or on the household appliance.

22. A piece of furniture includes at least one metal component according to claim 15, and the at least one metal component is arranged in or on the piece of furniture.

23. A fitting includes at least one metal component according to claim 15, and the at least one metal component is arranged in or on the fitting.

24. The method according to claim 15, further comprising the step of sintering the applied coating, the step of sintering occurring before the step of cooling.
